(19) United States
(12) Patent Application Publication
(10) Pub. No.: US 2017/0371441 A1
(43) Pub. Date: Dec. 28, 2017

(54) PRESSURE SENSOR WITH CAPACITIVE SHIELD

(71) Applicant: Microsoft Technology Licensing, LLC, Redmond, WA (US)

(72) Inventors: Marko Heikkinen, Tampere (FI); Joni Arola, Tampere (FI)

(73) Assignee: Microsoft Technology Licensing, LLC, Redmond, WA (US)

(21) Appl. No.: 15/189,944

(22) Filed: Jun. 22, 2016

(51) Int. Cl. G06F 3/044; H01L 27/32; G06F 3/041

(52) U.S. Cl. CPC G06F 3/044; G06F 3/0414; H01L 27/323; G06F 3/0412; G06F 2203/04107; G06F 2203/04105

(57) ABSTRACT

Techniques are described for pressure sensors used in display devices. In one embodiment, a capacitive shielding layer is used to block capacitive effects of user input from reaching sensor pads of the pressure sensor. In this way, the pressure sensor can extend into an active area of the display traditionally reserved for only touch sensors. The capacitive shielding layer can have gaps therein for allowing capacitive effects of touch input signals to pass to the touch sensors, while blocking the input signals from the pressure sensor. To reduce visibility of the pressure sensor in the active area, traces from both the pressure sensor and the capacitive shielding layer can be angled with respect to an edge of the display.

### BACKGROUND

Display devices are increasing in importance due to the wide-spread use of mobile devices, such as cell phones. There are numerous types of displays including Organic Light-emitting Diode (OLED) displays, Light-emitting Diode (LED) displays and Liquid Crystal Displays (LCD). The displays are used in a wide-range of applications, including consumer devices such as cell phones, gaming devices, watches, etc. The OLEDs use thin-film transistors in a backplane that switch pixels on or off so as to generate images on the display. LCDs, by contrast, typically use a backlight in conjunction with light-modulating properties of liquid crystals. Often the displays include multiple layers of glass. For example, an OLED display assembly can include a cover glass (also called a “window”), an encapsulation glass, and a Low-Temperature Polycrystalline Silicon (LTPS) glass.

There are numerous sensor types within the display devices. For example, touch sensors allow a user to touch a cover window of the display in order to select display elements. Capacitive effects of a user's finger can be detected using mutual capacitance wherein two conductive layers are stacked together with a thin separation there between. The layers can have columns and rows (TX and RX) of conductors and when a finger touches a point on the cover window, a mutual capacitance between the columns and rows is altered and detectable.

Pressure sensors also use capacitive effects, but based on a distance change between opposed plates of a capacitor. The pressure sensors are generally located within an inactive area of the cover window or below the display stack/system so as not to interfere with the touch sensors. More specifically, as both touch and pressure sensors use capacitive effects, a capacitance of a user's finger can be wrongly interpreted by the pressure sensor as a change in distance. Interference between pressure sensors and touch sensors can therefore be problematic and limits areas of the display which can be used for one or the other.

Therefore, there exists ample opportunity for improvement in technologies related to pressure sensors.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Technologies are described for a pressure sensor that can be included in both active and inactive areas of a display. Typically, a sensing pad of a pressure sensor is not within an active area of the display because interference from a user touch can result in inaccurate pressure sensing results. In one embodiment, a sensing pad can be extended into an active area of the display, but a capacitive shielding layer is placed between the sensing pad and the window substrate so as to block the capacitive effects of a user touch.

In another embodiment, the capacitive shielding layer can have gaps therein so as to allow the capacitive effects of a user's finger to pass to touch sensors that are positioned below the sensing pad.

In still another embodiment, the capacitive shielding layer is commensurate with the sensing pad or slightly larger than the sensing pad so as to block interfering signals related to touch from being received by the sensing pad. The pressure sensor can be formed from a plurality of conductive traces and the capacitive shielding layer can include a plurality of conductive traces that overlap with the traces of the pressure sensor.

The advantages of the described pressure sensor include the ability of the pressure sensor to extend into the active area of the display so as to provide a more accurate pressure sensor and to increase a usable space of the overall display.

As described herein, a variety of other features and advantages can be incorporated into the technologies as desired.

### BRIEF DESCRIPTION OF THE DRAWINGS

FIG. 1 is a system diagram of a display including a pressure sensor with a capacitive shield to block capacitive effects of a user touch.

FIG. 2 is an example of a display according to another embodiment, wherein a capacitive shield is used in conjunction with a pressure sensor.

FIG. 3 is an example of a display according to another embodiment, wherein a capacitive shield includes spaced-apart conductive traces that align with sensing pads of the pressure sensor.

FIG. 4 shows example layers of traces used for touch sensors, sensing pads of a pressure sensor and a capacitive shielding layer.

FIG. 5 shows an embodiment of sensing pads of a pressure sensor divided into different areas and possible configurations of the capacitive shielding layer.

FIG. 6 is a flowchart of a method according to one embodiment for using a display including a pressure sensor.

FIG. 7 is a diagram of an example computing system in which some described embodiments can be implemented.

### DETAILED DESCRIPTION

As described herein, various technologies can be applied to pressure sensors. It is desirable to have pressure sensors be extendible into an active area of a display, rather than have a designated inactive area for pressure sensors, which could limit the size of the display panel.

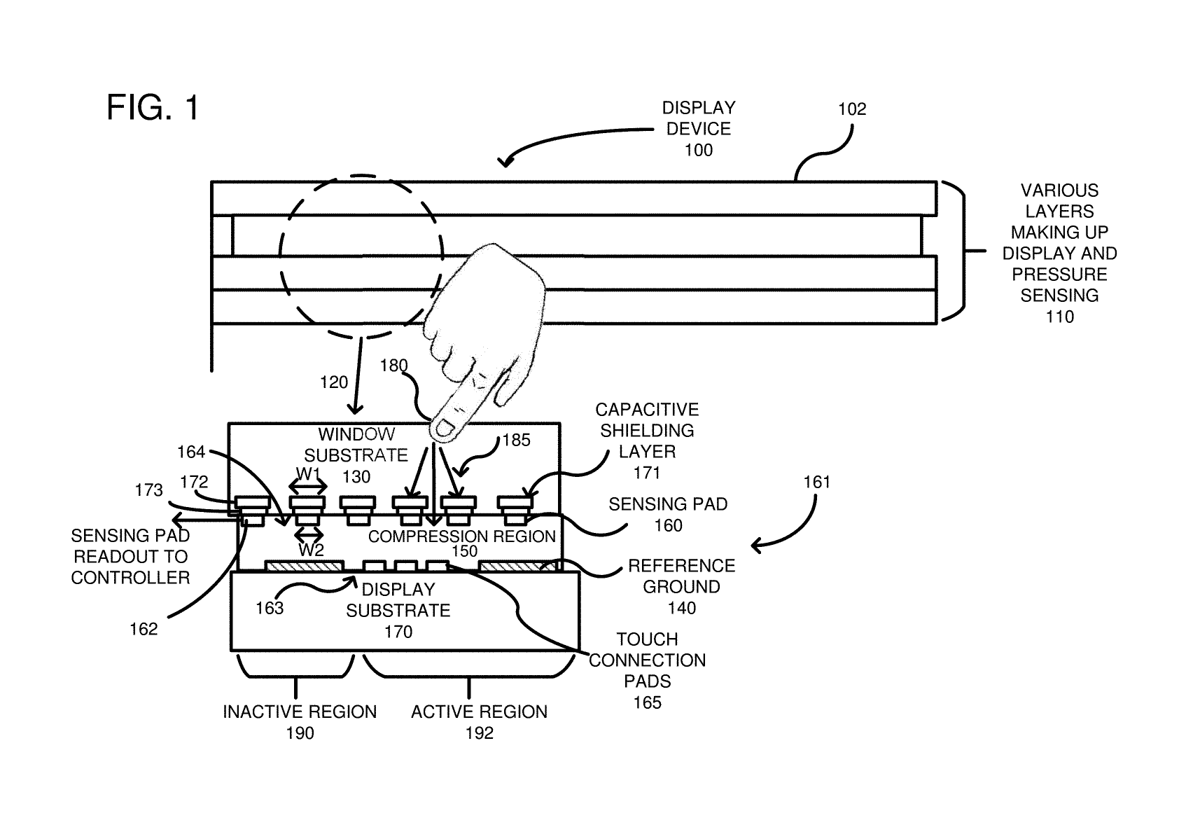

FIG. 1 is a display device (or assembly) 100 that can receive touch input and detect an amount of force thereon through a user press on a cover window 102. The display 100 can be used in a wide-range of applications, including consumer devices, such as cell phones, gaming devices, watches, etc. As shown at 110 generally, the display device 100 is made up of numerous layers, which can include one or more of the following: a glass layer or a substrate layer (e.g., plastics or other transparent materials), a polarizing layer, a compression layer, adhesive layers and a pressure sensor layer, all of which are described further below.

In this embodiment, the specific layers for a portion of the display are shown at 120. The specific layers include a window substrate 130, a reference ground 140, a compression region 150, a (pressure) sensing pad 160, a display substrate 170, and a capacitive shielding layer 171. It should be understood that at other locations in the display, the layers can be different. The window substrate 130 is often called a “cover” glass and can be made of glass, acrylic, polycarbonate, a variety of plastic materials, or other transparent materials.

The reference ground 140 is a layer of electrically conductive material, such as copper or Indium Tin Oxide (ITO), and can be coupled directly to the display substrate 170. In alternative embodiments, there can be one or more intermediate layers between the display substrate 170 and the reference ground layer 140. The reference ground layer is generally on an opposite side of the compression region 150 from the sensing pads 160 and can be positioned at other locations, such as embedded within the display substrate 170 or below the display substrate. The compression region 150 can be a compressible adhesive, such as a clear optical adhesive, a polymer, or a combination of an adhesive and a polymer. The compression region can deform and spring back based on a pressure exerted on the window substrate 130. For example, if a user presses on the window substrate 130, such pressure exerts a downward force on the compression region. The compression region 150 then compresses such that its width becomes less so that a distance between the reference ground 140 and the sensing pad 160 is reduced. Correspondingly, a capacitance formed by the reference ground layer 140 and the sensing pad 160 also changes. The amount of capacitance change corresponds directly to the force applied. As such, an amount of pressure exerted on the window substrate 130 by the user is detectable.

The sensing pad 160 is made of an electrically conductive material, such as copper or transparent conductive material, such as ITO. Additionally, the sensing pad 160 is coupled to a controller (not shown in this figure) so that the controller can read a capacitance change formed between the reference ground 140 and the sensing pad 160. The sensing pad 160 can be below the window substrate 130 and includes a plurality of individual conductive lines or traces, such as is shown at 162, with gaps, such as shown at 164 between the traces. The display substrate 170 can be an appropriate substrate for implementing OLED displays, including active-matrix organic light-emitting diode (AMOLED), LED displays, LCDs, etc. As such, the display substrate 170 can be formed from multiple layers of glass or other substrates, such as plastic. For example, an OLED display can be formed from an encapsulation glass and an LTPS glass. Other combinations can be used. The sensing pad 160 and the reference ground 140, together form a pressure sensor 161.

Touch sensors 163 include individual touch sensing pads or area 165 that are spaced apart. The touch sensors 163 receive capacitive touch signals 185 transmitted by a user touch, shown generally at 180. The touch sensors 163 are formed from conductive material, such as copper and can detect mutual capacitance change so as determine a location of the user touch.

A capacitive shielding layer 171, which is also, more generically, called a shield or guard layer, is a conductive layer (e.g., made of copper, ITO or other conductive material) that can be coupled to ground or any desired voltage level. The capacitive shielding layer 171 is aligned with the sensing pads 160 so as to act as an electrical shield for the sensing pads. For example, the capacitive shielding layer 171 can include individual conductive lines or traces, such as is shown at 172, which overlap the traces of the sensing pad 160. The width of the traces of the capacitive shielding layer 171 can be a first width, shown at W1. The width of the traces of the sensing pad 160 is shown as a second width, W2. Generally, the width W1 is greater than the width W2 so that the capacitive shielding layer 171 can adequately block undesirable electrical input signals. For example, as shown at 180, the user can touch the window substrate 130 so as to select an icon or perform some other user interface feature. Such a touch of the user interface generates capacitive signals, shown by arrows 185. Some of the capacitive signals are blocked by the capacitive shielding layer 171 while other capacitive signals pass through the gaps 164 so as to reach the touch sensors 163. By shielding the capacitive signals 185 from the sensing pads 160, the pressure sensor 161 can obtain a more accurate pressure reading without interference from the capacitive touch signals. Additionally, the sensing pads 160 of the pressure sensor 161 can be extended into either an inactive region 190 of the display or an active region 192 so as to provide a greater flexibility in terms of location over past pressure sensors. A non-conductive passivation layer 173 is positioned between the sensing pad 160 and the capacitive shielding layer 171 so as to prevent current flow there between.

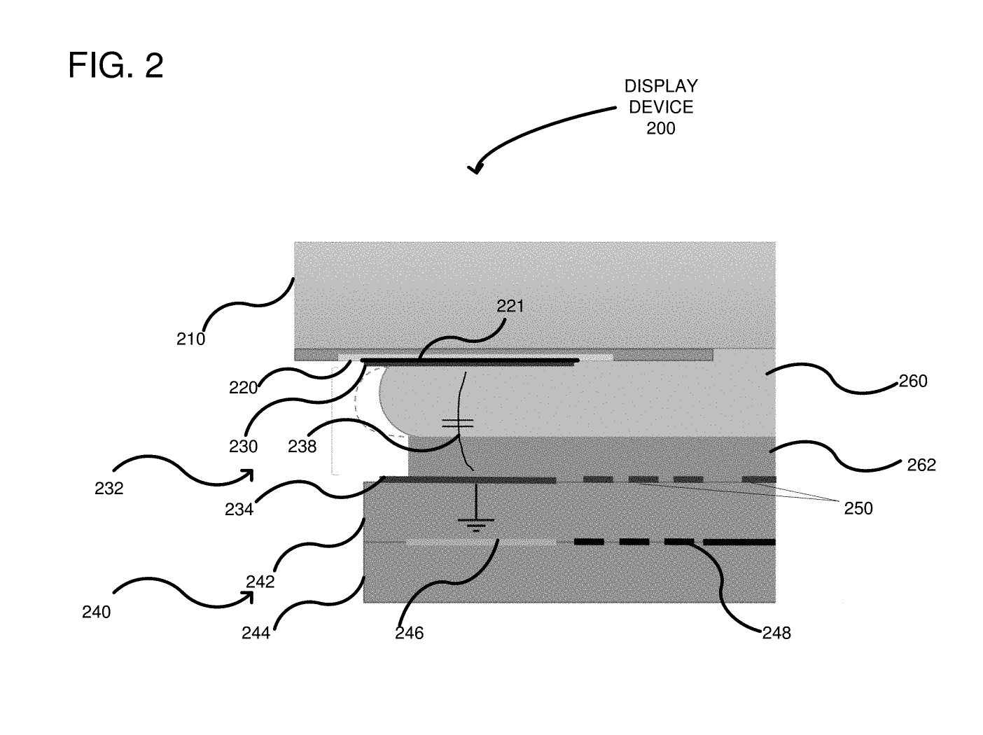

FIG. 2 is an example of a display device (or assembly) 200 according to another embodiment, wherein a capacitive shield is used in conjunction with a pressure sensor. In this embodiment, a window substrate 210 is a transparent material, such as glass, for displaying elements on the display device 200 and for receiving user touch input. A capacitive shielding layer 220 is positioned below the window substrate 210 and can be coupled thereto or there can be one or more intermediate layers between the capacitive shielding layer 220 and the window substrate 210. The capacitive shielding layer 220 is directly above a sensing pad 230 of a pressure sensor 232, which is formed, in part, by the sensing pads 230 and a reference ground layer 234. A non-conductive layer 221 can be positioned between the capacitive shielding layer 220 and the sensing pad 230, for the reasons described above. The reference ground layer 234 can be positioned on top of a display substrate 240 that includes an encapsulation layer 242 and an LTPS layer 244. The pressure sensor 232 measures a capacitance value 238 between the sensing pad 230 and the reference ground layer 234. Both the encapsulation layer 242 and LTPS layer 244 can be formed of glass, and bound together using a frit layer 246. Display traces 248 are positioned between the encapsulation layer 242 and the LTPS layer 244 and are used in conjunction with other display elements to project images through the window substrate 210.

Touch traces 250 are positioned on the encapsulation layer 242. The touch traces 250 can receive capacitive signals from a user touch on the window substrate 210 so as to determine a position of the user's touch. A compression region 260 is positioned between the sensing pad 230 and the reference ground layer 234. A polarizer layer 262 is positioned between the compression region 260 and the touch traces 250. The polarizer layer 262 enhances the contrast of the display substrate. The LTPS glass 244, encapsulation glass 242 and polarizer 262 together form an AMOLED display.

As described above, the capacitive shielding 220 blocks capacitive signals that can impact a capacitance reading 238 between the sensing pad 230 and the reference ground layer 234. As such, the sensing pad 230 can be positioned within an inactive area of the display or an active area. The pressure sensor 240 in this embodiment includes the sensing pads 230, the reference ground layer 234, the compression region 260 and the capacitive shielding 220.

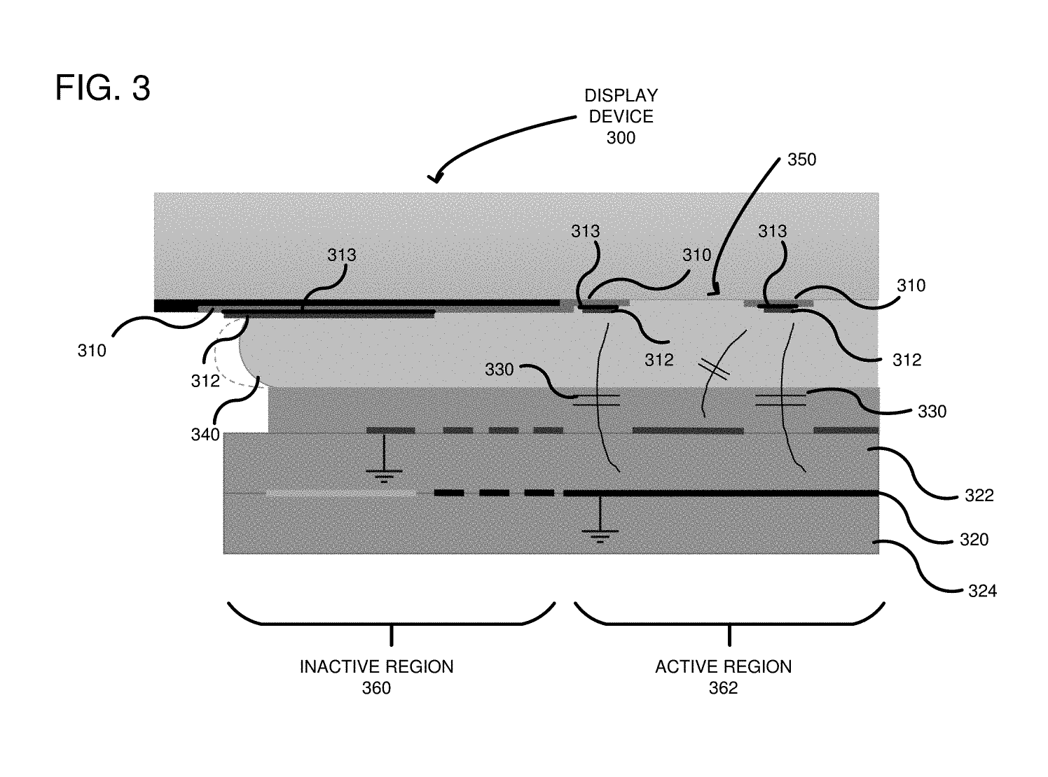

FIG. 3 shows another embodiment of a display device (or assembly) 300. In this embodiment, capacitive shielding layer 310 is shown overlapping sensing pad traces 312 of a pressure sensor. A non-conductive layer 313 can be positioned between the capacitive shielding layer 310 and the sensing pad traces 312 so as to prevent current flow there between. In this embodiment, a reference ground layer 320, which is part of the pressure sensor, is embedded between an encapsulation layer 322 and an LTPS layer 324. Other types of display substrates can be used instead. A capacitance 330 can be formed between the sensing pad traces 312 and the reference ground layer 320. The display device 300 illustrates that the reference ground layer 320 can be positioned at multiple different locations below a compression region 340. The sensing pad traces 312 are above the compression region 340 and the sensing pad traces 312 have gaps 350 there between. The capacitive shielding layer 310 also has the gaps 350 between the traces so as to allow capacitive touch signals to pass through the capacitive shielding layer to the touch sensors. FIG. 3 also illustrates that the capacitive shielding layer 310 can vary in width. For example, in an inactive region 360 the sensing pads 312 can be wider than in an active region 362. Correspondingly, the capacitive shielding traces can be wider in the inactive region 360 so as to shield the sensing pads from capacitive touch signals. In any case, the sensing pads 312 of the pressure sensor can be in both the inactive region 360 and/or the active region 362. The use of the capacitive shielding layer 310 makes any capacitance generated by a user's finger invisible to the pressure sensor.

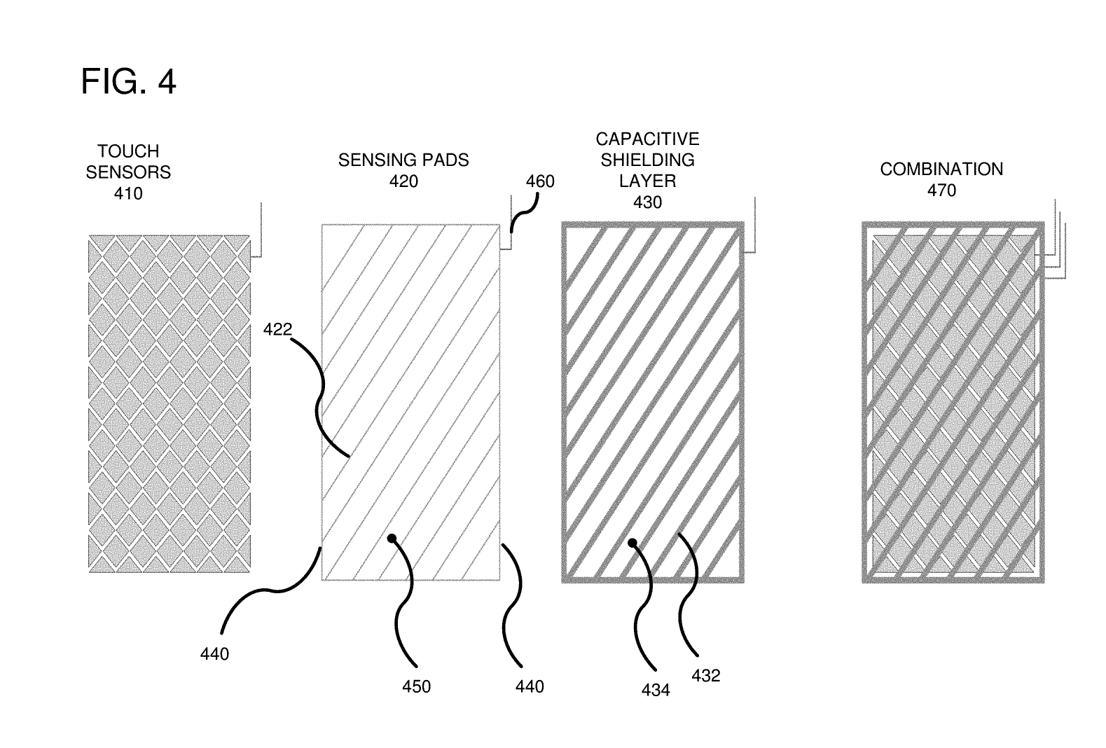

FIG. 4 illustrates an embodiment for configuration of touch sensors 410, sensing pads 420 and a capacitive shielding layer 430. The touch sensors 410 can include a plurality of metal traces in a lattice pattern. The lattice pattern is formed by rows and columns, TX and RX traces in separate layers with a thin separation between the two layers. When a finger touches the window substrate, a mutual capacitance between the rows and columns is reduced. This reduction in capacitance can be used to identify the presence and location of a finger. Although this embodiment shows a mutual capacitance structure, other touch sensing structures can be used such as surface capacitance, projected capacitance, and self capacitance.

The sensing pads 420 are shown as being a plurality of traces 422 at an angle with respect to the edges 440 of the display. The sensing pads 420 are electrically coupled together, but have gaps 450 between the traces. The gaps 450 are sized such that capacitive signals from a finger touch can bypass the sensing pads 420 to reach the touch sensors 410. A single output 460 from the sensing pads 420 can be sufficient to sense pressure. The capacitive shielding layer 430 can also have a plurality of traces 432 designed to overlay the traces of the sensing pads 420. The traces of the capacitive shielding layer 430 are wider than those of the sensing pads 420 so as to ensure that the sensing pad traces are adequately shielded. Additionally, the traces 432 of the capacitive shielding layer 430 has gaps 434 there between. A combination of the layers is shown at 470 with the touch sensors 410 being below the sensing pads 420, which are below the capacitive shielding layer 430. The sensing pads 420 should be sufficiently transparent so that visibility of the display content is not disturbed. Additionally, disturbance of the touch functionality is minimized The narrow sensing pads 420 together with the capacitive shielding layer 430 accomplishes these goals. The angled traces of the sensing pads 420 and the capacitive shielding layer 430 assist in hiding the pattern on the window substrate so it is less visible to users.

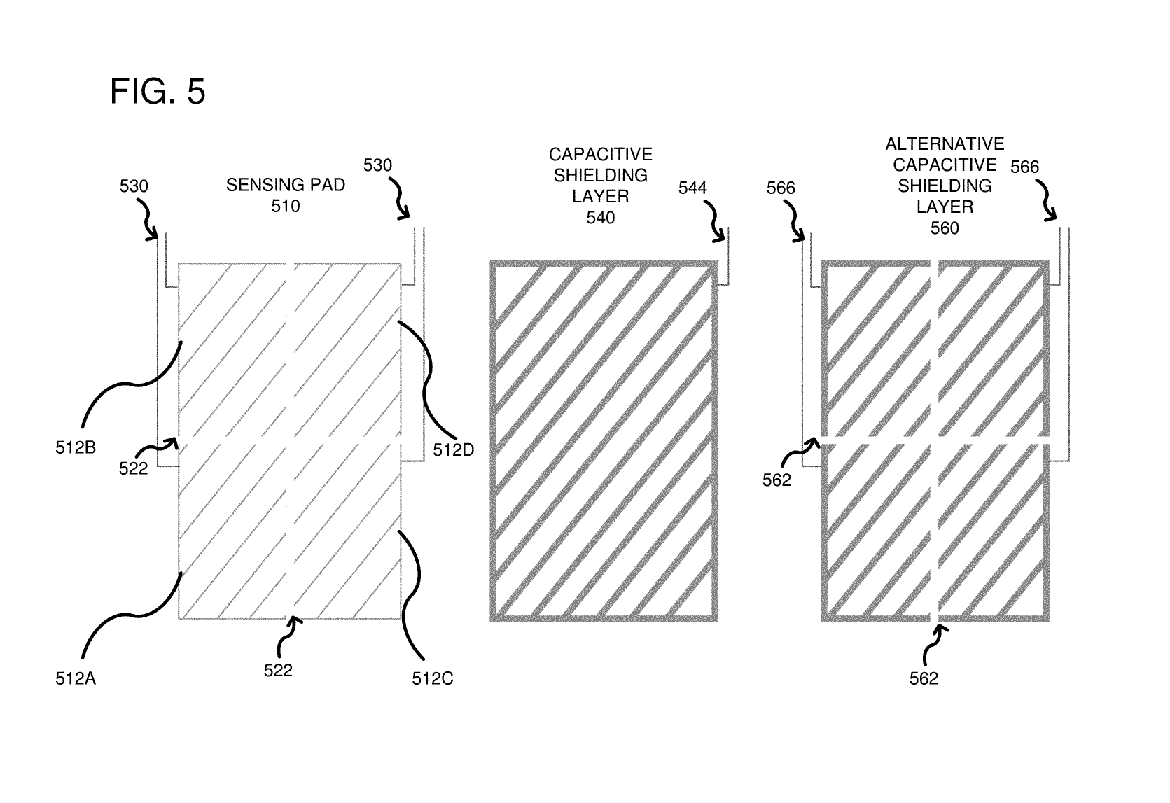

FIG. 5 illustrates another embodiment of the sensing pads 510 and capacitive shielding layer 540. In this embodiment, the sensing pad 510 has four electrically separate zones 512A-512D. Each zone has a physical gap between it and the adjacent zones, as is shown generally at 522. Each zone has a separate pressure sensing output shown by output wires 530. The capacitive shielding layer 540 is shown as an electrically unitary layer with angled traces that overlap the traces of the sensing pad 510. The capacitive shielding layer 540 need not have gaps 522 that are present in the sensing pad 510. A single input 544 can supply ground or another voltage level to the capacitive shielding layer 540.

An alternative capacitive shielding layer 560 can have gaps 562 that align with the gaps 522 in the sensing pad 510 so as to have electrically different sections of the capacitive shielding layer 560. Different input voltages can be supplied to each section as shown at 566, so that different shielding voltages can be applied to different sections of the display, based on the desired requirements.

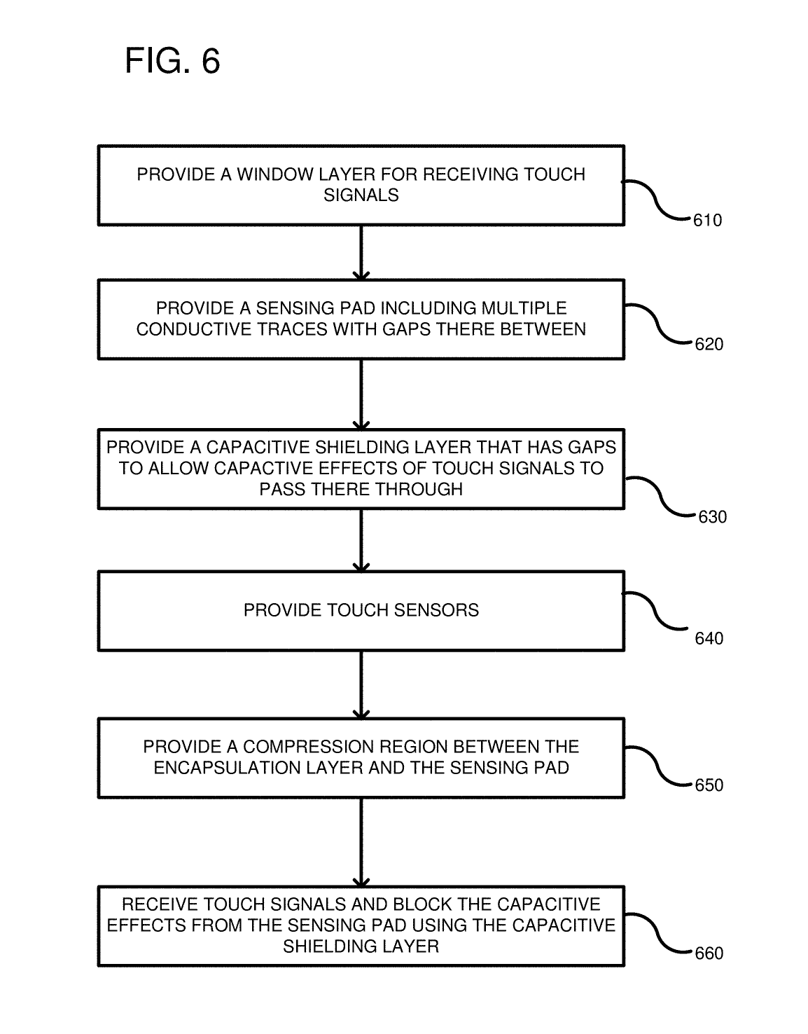

FIG. 6 is a method of using a display including a pressure sensor. In process block 610, a window layer is provided for receiving touch signals. The window layer is generally a cover glass upon which the user touches to provide user input. In process block 620, a sensing pad is provided. The sensing pad can include multiple conductive traces with gaps between the traces. For example, FIG. 4 shows a sensing pad having conductive traces 422 with gaps 450 there between. The thicknesses of the traces and gaps are sized so as to minimize interference with touch signals provided by user input. In process block 630, a capacitive shielding layer is provided that has gaps therein to allow capacitive effects of touch signals to pass. For example, returning to FIG. 4, the capacitive shielding layer is shown with conductive traces 432 with gaps 434 there between so as to match the gaps in the sensing pads 420. In process block 640, touch sensors are provided, such as the touch sensors 410 of FIG. 4. In process block 650, a compression region is provided between the encapsulation layer and the sensing pads. For example, in FIG. 2, a compression region is shown at 260 between the encapsulation layer 242 and the sensing pad 230. In process block 660, touch signals are received, such as from a user, and the capacitive effects of the touch signals are blocked from reaching the sensing pad using the capacitive shielding layer. For example, FIG. 1 shows the capacitive touch signals 185 being blocked by the capacitive shielding layer 171. This ensures that the sensing pad is not impacted by the capacitive effects of a user finger.

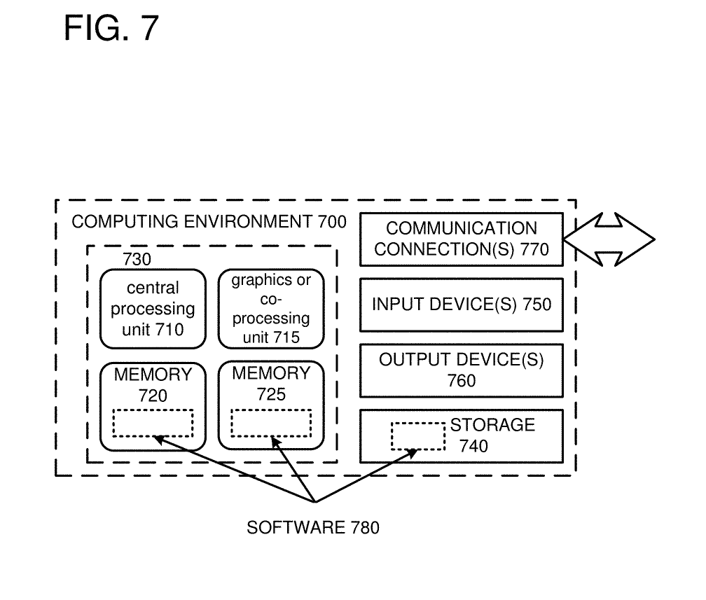

FIG. 7 depicts a generalized example of a suitable computing system 700 in which the described innovations may be implemented. The computing system 700 is not intended to suggest any limitation as to scope of use or functionality, as the innovations may be implemented in diverse general-purpose or special-purpose computing systems.

With reference to FIG. 7, the computing system 700 includes one or more processing units 710, 715 and memory 720, 725. In FIG. 7, this basic configuration 730 is included within a dashed line. The processing units 710, 715 execute computer-executable instructions. A processing unit can be a general-purpose central processing unit (CPU), processor in an application-specific integrated circuit (ASIC), or any other type of processor. Such a processor can be used to read an output from the sensing pad, as was illustrated in FIG. 1. In a multi-processing system, multiple processing units execute computer-executable instructions to increase processing power. For example, FIG. 7 shows a central processing unit 710 as well as a graphics processing unit or co-processing unit 715. The tangible memory 720, 725 may be volatile memory (e.g., registers, cache, RAM), non-volatile memory (e.g., ROM, EEPROM, flash memory, etc.), or some combination of the two, accessible by the processing unit(s). The memory 720, 725 stores software 780 implementing one or more innovations described herein, in the form of computer-executable instructions suitable for execution by the processing unit(s).

A computing system may have additional features. For example, the computing system 700 includes storage 740, one or more input devices 750, one or more output devices 760, and one or more communication connections 770. An interconnection mechanism (not shown) such as a bus, controller, or network interconnects the components of the computing system 700. Typically, operating system software (not shown) provides an operating environment for other software executing in the computing system 700, and coordinates activities of the components of the computing system 700.

The tangible storage 740 may be removable or non-removable, and includes magnetic disks, magnetic tapes or cassettes, CD-ROMs, DVDs, or any other medium which can be used to store information and which can be accessed within the computing system 700. The storage 740 stores instructions for the software 780.

The input device(s) 750 may be a touch input device such as a touch display, a keyboard, mouse, pen, or trackball, a voice input device, a scanning device, or another device that provides input to the computing system 700. For video encoding, the input device(s) 750 may be a camera, video card, TV tuner card, or similar device that accepts video input in analog or digital form, or a CD-ROM or CD-RW that reads video samples into the computing system 700. The output device(s) 760 may be a display, printer, speaker, CD-writer, or another device that provides output from the computing system 700.

The communication connection(s) 770 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

The innovations can be described in the general context of computer-executable instructions, such as those included in program modules, being executed in a computing system on a target real or virtual processor. Generally, program modules include routines, programs, libraries, objects, classes, components, data structures, etc. that perform particular tasks or implement particular abstract data types. The functionality of the program modules may be combined or split between program modules as desired in various embodiments. Computer-executable instructions for program modules may be executed within a local or distributed computing system.

The terms “system” and “device” are used interchangeably herein. Unless the context clearly indicates otherwise, neither term implies any limitation on a type of computing system or computing device. In general, a computing system or computing device can be local or distributed, and can include any combination of special-purpose hardware and/or general-purpose hardware with software implementing the functionality described herein.

For the sake of presentation, the detailed description uses terms like “determine” and “use” to describe computer operations in a computing system. These terms are high-level abstractions for operations performed by a computer, and should not be confused with acts performed by a human being. The actual computer operations corresponding to these terms vary depending on implementation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

Any of the disclosed methods can be implemented as computer-executable instructions or a computer program product stored on one or more computer-readable storage media and executed on a computing device (e.g., any available computing device, including smart phones or other mobile devices that include computing hardware). Computer-readable storage media are any available tangible media that can be accessed within a computing environment (e.g., one or more optical media discs such as DVD or CD, volatile memory components (such as DRAM or SRAM), or nonvolatile memory components (such as flash memory or hard drives)). By way of example and with reference to FIG. 7, computer-readable storage media include memory 720 and 725, and storage 740.

Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or other such network) using one or more network computers.

The disclosed methods, apparatus, and systems should not be construed as limiting in any way. Instead, the present disclosure is directed toward all novel and nonobvious features and aspects of the various disclosed embodiments, alone and in various combinations and sub combinations with one another. The disclosed methods, apparatus, and systems are not limited to any specific aspect or feature or combination thereof, nor do the disclosed embodiments require that any one or more specific advantages be present or problems be solved.

The technologies from any example can be combined with the technologies described in any one or more of the other examples. In view of the many possible embodiments to which the principles of the disclosed technology may be applied, it should be recognized that the illustrated embodiments are examples of the disclosed technology and should not be taken as a limitation on the scope of the disclosed technology.

The following paragraphs further describe embodiments of the display:

A. A display, comprising:

a window substrate having an inactive area and an active area;

a compression region below the window substrate, the compression region being compressible when force is applied to the window substrate;

touch sensors below the compression region in the active area of the window substrate;

a pressure sensor including a sensing pad positioned between the compressible region and the window substrate, the pressure sensor used to detect when the compression region has force applied thereon; and

a capacitive shielding layer between the sensing pad and the window substrate, the capacitive shielding for blocking capacitive effects of a user touch on the window substrate from the pressure sensor.

B. The display of paragraph A, wherein the capacitive shielding layer is formed from conductive material with gaps therein for allowing capacitive effects of the user touch to pass through to the touch sensors.

C. The display of any of paragraphs A-B, wherein the pressure sensor is partially in the active area of the window substrate and overlaps with the touch sensors.

D. The display of any of paragraphs A-C, wherein the sensing pad includes conductive traces of a first width and the capacitive shielding layer includes conductive traces of a second width, which is wider than the first width, and overlaps with the conductive traces of the sensing pad so as to shield the pressure sensor from the capacitive effects.

E. The display of paragraph D, wherein the window substrate includes first and second edges and wherein the conductive traces of the sensing pad are at an angle with respect to the first and second edges.

F. The display of paragraph D, wherein the conductive traces of the sensing pad are electrically divided into multiple areas and wherein the conductive traces of the capacitive shielding layer is electrically a single layer.

G. The display of any of paragraphs A-F, wherein the compression region is an adhesive, a polymer or a combination thereof.

H. The display of any of paragraphs A-G, wherein the window substrate is made of glass or plastic.

I. The display of any of paragraphs A-H, wherein the pressure sensor further includes a ground layer below the compression region which forms a capacitor with the sensing pad.

J. A display device including a pressure sensor, comprising:

a window substrate;

a sensing pad of the pressure sensor;

a capacitive shielding layer between the sensing pad and the window substrate;

a reference ground layer below the sensing pad; and

a compression region between the sensing pad and the reference ground layer.

K. The display device of paragraph J, wherein the capacitive shielding layer is a conductive layer having a voltage applied thereto or ground applied thereto.

L. The display device of any of paragraphs J-K, further including touch sensors below the capacitive shielding layer, wherein the capacitive shielding layer has gaps therein to allow capacitive touch signals to pass through the capacitive shielding layer to the touch sensors.

M. The display device of any of paragraphs J-L, wherein the sensing pad includes multiple conductive traces in parallel having a first width and the capacitive shielding layer includes multiple conductive traces in parallel having a second width, wider than the first width, wherein the multiple conductive traces of the capacitive shielding layer cover the multiple conductive traces of the sensing pad.

N. The display device of paragraph M, wherein the multiple conductive traces of the sensing pad are electrically divided into multiple zones having separate electrical outputs.

O. The display device of any of paragraphs J-N, wherein the window substrate includes an active area, and an inactive area, and wherein the sensing pad is at least partially within the active area.

P. The display device of any of paragraphs J-O, wherein the compression region is a compressible adhesive.

Q. The display device of any of paragraphs J-P, further including an encapsulation layer below the reference ground layer and further including touch sensors on the encapsulation layer.

R. A method of using a display including a pressure sensor, comprising:

providing a window layer for receiving user touch signals;

providing a sensing pad of a pressure sensor between the window layer and an encapsulation layer, the sensing pad including multiple conductive traces with gaps between the traces;

providing a capacitive shielding layer between the sensing pad and the window layer to shield the sensing pad from the touch signals, wherein the capacitive shielding layer has gaps therein to allow capacitive effects of the touch signals to pass through the capacitive shielding layer;

providing touch sensors above the encapsulation layer;

providing a compression region between the encapsulation layer and the sensing pad; and

receiving touch signals on the window layer, and blocking capacitive effects of the touch signals from the sensing pad using the capacitive shielding layer, and allowing the capacitive effects to pass to the touch sensors through the gaps in the capacitive shielding layer.

S. The method of paragraph R, further including receiving a pressure on the window layer that compresses the compression region; and

sensing a change in capacitance using the sensing pad due to a change in distance between the sensing pad and a reference ground layer on an opposite side of the compression region from the sensing pad.

T. The method of any of paragraphs R-S, wherein the capacitive shielding layer comprises multiple traces at an angle with respect to an edge of the window layer.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope of these claims.

What is claimed is:

1. A display, comprising:
a window substrate having an inactive area and an active area;
a compression region below the window substrate, the compression region being compressible when force is applied to the window substrate;
touch sensors below the compression region in the active area of the window substrate;
a pressure sensor including a sensing pad positioned between the compressible region and the window substrate, the pressure sensor used to detect when the compression region has force applied thereon; and
a capacitive shielding layer between the sensing pad and the window substrate, the capacitive shielding for blocking capacitive effects of a user touch on the window substrate from the pressure sensor.

2. The display of claim 1, wherein the capacitive shielding layer is formed from conductive material with gaps therein for allowing capacitive effects of the user touch to pass through to the touch sensors.

3. The display of claim 1, wherein the pressure sensor is partially in the active area of the window substrate and overlaps with the touch sensors.

4. The display of claim 1, wherein the sensing pad includes conductive traces of a first width and the capacitive shielding layer includes conductive traces of a second width, which is wider than the first width, and overlaps with the conductive traces of the sensing pad so as to shield the pressure sensor from the capacitive effects.

5. The display of claim 4, wherein the window substrate includes first and second edges and wherein the conductive traces of the sensing pad are at an angle with respect to the first and second edges.

6. The display of claim 4, wherein the conductive traces of the sensing pad are electrically divided into multiple areas and wherein the conductive traces of the capacitive shielding layer is electrically a single layer.

7. The display of claim 1, wherein the compression region is an adhesive, a polymer or a combination thereof.

8. The display of claim 1, wherein the window substrate is made of glass or plastic.

9. The display of claim 1, wherein the pressure sensor further includes a ground layer below the compression region which forms a capacitor with the sensing pad.

10. A display device including a pressure sensor, comprising:
a window substrate;
a sensing pad of the pressure sensor;
a capacitive shielding layer between the sensing pad and the window substrate;
a reference ground layer below the sensing pad; and
a compression region between the sensing pad and the reference ground layer.

11. The display device of claim 10, wherein the capacitive shielding layer is a conductive layer having a voltage applied thereto or ground applied thereto.

12. The display device of claim 10, further including touch sensors below the capacitive shielding layer, wherein the capacitive shielding layer has gaps therein to allow capacitive touch signals to pass through the capacitive shielding layer to the touch sensors.

13. The display device of claim 10, wherein the sensing pad includes multiple conductive traces in parallel having a first width and the capacitive shielding layer includes multiple conductive traces in parallel having a second width, wider than the first width, wherein the multiple conductive traces of the capacitive shielding layer cover the multiple conductive traces of the sensing pad.

14. The display device of claim 13, wherein the multiple conductive traces of the sensing pad are electrically divided into multiple zones having separate electrical outputs.

15. The display device of claim 10, wherein the window substrate includes an active area, and an inactive area, and wherein the sensing pad is at least partially within the active area.

16. The display device of claim 10, wherein the compression region is a compressible adhesive.

17. The display device of claim 10, further including an encapsulation layer below the reference ground layer and further including touch sensors on the encapsulation layer.

18. A method of using a display including a pressure sensor, comprising:
providing a window layer for receiving user touch signals;
providing a sensing pad of a pressure sensor between the window layer and an encapsulation layer, the sensing pad including multiple conductive traces with gaps between the traces;
providing a capacitive shielding layer between the sensing pad and the window layer to shield the sensing pad from the touch signals, wherein the capacitive shielding layer has gaps therein to allow capacitive effects of the touch signals to pass through the capacitive shielding layer;
providing touch sensors above the encapsulation layer;
providing a compression region between the encapsulation layer and the sensing pad;
and
receiving touch signals on the window layer, and blocking capacitive effects of the touch signals from the sensing pad using the capacitive shielding layer, and allowing the capacitive effects to pass to the touch sensors through the gaps in the capacitive shielding layer.

19. The method of claim 18, further including receiving a pressure on the window layer that compresses the compression region; and
sensing a change in capacitance using the sensing pad due to a change in distance between the sensing pad and a reference ground layer on an opposite side of the compression region from the sensing pad.

20. The method of claim 18, wherein the capacitive shielding layer comprises multiple traces at an angle with respect to an edge of the window layer.
